(19) United States
(12) Patent Application Publication
(10) Pub. No.: US 2008/0019166 A1
(43) Pub. Date: Jan. 24, 2008

(54) DISPLAY SUBSTRATE AND DISPLAY DEVICE HAVING THE SAME

(75) Inventors: Min-Kyung JUNG, Suwon-si (KR); Jin JEON, Suwon-si (KR); Young-Bae JUNG, Hwaseong-si (KR); Young-Han PARK, Anyang-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/763,668

(22) Filed: Jun. 15, 2007

(30) Foreign Application Priority Data
Jun. 19, 2006 (KR) 2006-054792

(51) Int. Cl. G11C 11/22

(52) U.S. Cl. 365/145

(57) ABSTRACT

A display substrate includes a base substrate having a display area displaying an image and a peripheral area surrounding the display area the base substrate including a plurality of gate lines comprising a first gate line group and a second gate line group, a first dispersion circuit part formed at a first end portion of the first gate line group, a second dispersion circuit part formed at a second end portion of the second gate line group, a first dispersion line electrically connecting to the first gate line group through the first dispersion circuit part. a second dispersion line electrically connecting to the second gate line group through the second dispersion circuit part and a third dispersion line connecting the first dispersion line with the second dispersion line.

### CROSS-REFERENCE TO RELATED APPLICATION

The present application claims priority to Korean Patent Application No.2006-054792, filed on Jun. 19, 2006, the disclosure of which is incorporated herein by reference in its entirety.

### BACKGROUND OF THE INVENTION

1. Technical Field

The present disclosure relates to a display substrate and a display device having the display substrate, and more particularly, to a display substrate capable of improving a malfunction caused by an electro static.

2. Discussion of the Related Art

A liquid crystal display (LCD) device can include a display panel and a driving apparatus. The display panel can include an array substrate, a countering substrate, such as a color filter substrates facing the array substrate, and a liquid crystal layer interposed between the array substrate and the countering substrate.

The array substrate can include a plurality of gate lines, a plurality of data lines, and a plurality of thin film transistors (TFTs) connecting to the plurality of gate lines and the plurality of data lines. When a pattern design having a high metal density, such as an amorphous silicon gate (ASG) technology, a chip on glass (COG) technology is employed on the array substrate, the array substrate can be more susceptible to damage caused by an electro static.

Moreover, when the array substrate and the display panel are manufactured, an electro static generated during process can be flowed to a metal line formed on the array substrate, so that a disconnection or short-circuit of the metal line can be occurred. The TFTs can be also deteriorated due to the electro static.

### SUMMARY OF THE INVENTION

According to an exemplary embodiment of the present invention, a display substrate includes a base substrate having a display area displaying an image and a peripheral area surrounding the display area, the base substrate including a plurality of gate lines comprising a first gate line group and a second gate line group, a first dispersion circuit part formed at a first end portion of the first gate line group, a second dispersion circuit part formed at a second end portion of the second gate line group, a first dispersion line electrically connected to the first gate line group through the first dispersion circuit part, a second dispersion line electrically connected to the second gate line group through the second dispersion circuit part, and a third dispersion line connecting the first dispersion line with the second dispersion line

The peripheral area may include a first peripheral area disposed at a first end portion of the plurality of gate lines and a second peripheral area disposed at a second end portion of the plurality of gate lines.

The first dispersion circuit part and the first dispersion line can be formed in the first peripheral area, and the second dispersion circuit part and the second dispersion lines can be formed in the second peripheral area.

The first dispersion circuit part may comprise a first transistor including a control electrode, a first electrode connected to the first gate line group, and a second electrode connected to the first dispersion line, and a second transistor including a control electrode, a first electrode connected to the first dispersion line, and a second electrode connected to the first gate line group.

The second dispersion circuit part may comprise a third transistor including a control electrode, a first electrode connected to the second gate line group, and a second electrode connected to the second dispersion line, and a fourth transistor including a control electrode, a first electrode connected to the second dispersion line, and a second electrode connected to the second gate line group

The first dispersion circuit part may comprise a first diode including an anode connected to the first gate line group and a cathode connected to the first dispersion line, and a second diode including an anode connected to the first dispersion line and a cathode connected to the first gate line group.

The second dispersion circuit part may comprise a third diode including an anode connected to the second gate line group and a cathode connected to the second dispersion line, and a fourth diode including an anode connected to the second dispersion line and a cathode connected to the second gate line group.

The first gate line group may include odd-numbered gate lines and the second gate line group includes even-numbered gate lines.

The third dispersion line can be formed in the peripheral area.

According to an exemplary embodiment of the present invention, a display device comprises an array substrate having a display area displaying an image and a peripheral area surrounding the display area, the array substrate including a plurality of gate lines comprising a first gate line group and a second gate line group, a first dispersion circuit part formed at a first end portion of the first gate line group, a second dispersion circuit part formed at a second end portion of the second gate line group, a first dispersion line electrically connected to the first gate line group through the first dispersion circuit part, a second dispersion line electrically connected to the second gate line group through the second dispersion circuit part, a third dispersion line connecting the first dispersion line with the second dispersion line, a countering substrate facing the array substrate, a first gate circuit part to drive the first gate line group, and a second gate circuit part to drive the second gate line group.

The first dispersion circuit part, the second dispersion circuit part, the first dispersion line the second dispersion line and the third dispersion line can be formed in the peripheral area.

According to exemplary embodiments of the present invention, electro static discharge can be dispersed to a plurality of gate lines so that lines and a pixel element of a display area can be prevented from being damaged.

### BRIEF DESCRIPTION OF THE DRAWINGS

Exemplary embodiments of the present invention can be understood in more detail from the following descriptions taken in conjunction with the accompanying drawings in which:

FIG. 1 is a plan view showing a display device according to an exemplary embodiment of the present invention;

FIG. 2a is an equivalent circuit diagram of a first dispersion circuit part shown in FIG. 1;

FIG. 2b is an equivalent circuit diagram of a second dispersion circuit part shown in FIG. 1;

FIG. 3 is an equivalent circuit diagram of a display substrate according to an exemplary embodiment of the present invention;

FIG. 4a is an equivalent circuit diagram of a first dispersion circuit part shown in FIG. 1 according to an exemplary embodiment of the present invention; and

FIG. 4b is an equivalent circuit diagram of a second dispersion circuit part shown in FIG. 1 according to an exemplary embodiment of the present invention.

### DESCRIPTION OF THE EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein.

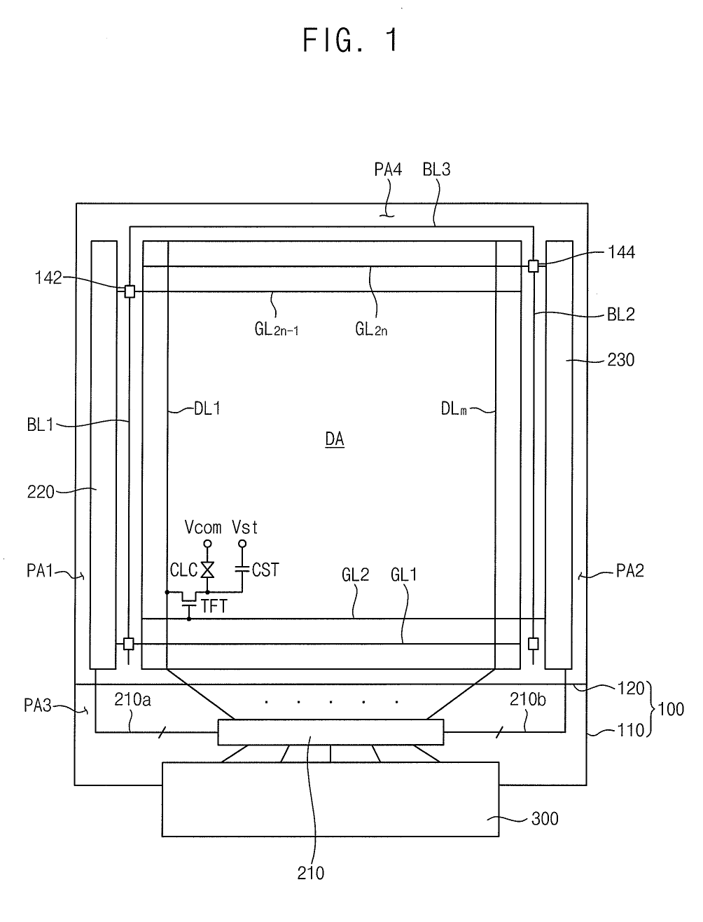

FIG. 1 is a plan view showing a display device according to an exemplary embodiment of the present invention.

Referring to FIG. 1, a display device may comprise a display panel 100, a driving circuit part and a flexible printed circuit board (PCB) 300. The driving circuit part may comprise a first gate circuit part 220, a second gate circuit part 230, and a driving part 210. The flexible PCB electrically connects an external device with the driving circuit part.

The display panel 100 may comprise an array substrate 110, a countering substrate 120, such as a color filter, and a liquid crystal layer (not shown) interposed between the array substrate 110 and the countering substrate 120. The array substrate 110 may include a display area DA and a peripheral area PA surrounding the display area DA.

The display area DA may include a plurality of gate lines GL1˜GL2n formed in a first direction, a plurality of data lines DL1˜DLm formed in a second direction, and a plurality of pixel parts electrically connecting the plurality of gate lines GL1˜GL2n and the plurality of data lines DL1˜DLm. In an embodiments the first direction can cross the second direction. Each pixel part may comprise a thin film transistor (TFT) connecting to the gate line GL and the data line DL, a pixel electrode (not shown) electrically connecting to the TFT, and a storage capacitor CST. The pixel electrode (not shown) can act as a first electrode of the liquid crystal capacitor CLC. In an embodiment, a gate electrode of the TFT connects to the gate line GC, a source electrode of the TFT connects to the data line DL, and a drain electrode of the TFT connects to the pixel electrode and the storage capacitor CST.

The peripheral area PA may include a first peripheral area PA1 disposed at a first end portion of the plurality of gate lines GL1˜GL2n, a second peripheral area PA2 disposed at a second end portion of the plurality of gate lines GL1˜GL2n, a third peripheral area PA3 disposed at a first end portion of the plurality of data lines DL1˜DLm, and a fourth peripheral area PA4 disposed at a second end portion of the plurality of data lines DL1˜DLm.

The first peripheral area PA1 may include a shift register having a plurality of stages, the first gate circuit part 220 to output a gate signal to a first gate lines group of the plurality of gate lines GL1˜GL2n. In an embodiment, the first gate lines group of the plurality of gate lines GL1˜GL2n may include an odd-numbered gate tines GL1, GL3 . . . GL2n-1.

The first peripheral area PA1 may further include first dispersion circuit parts 142, and a first dispersion line BL1 to interconnect the first dispersion circuit parts 142. The first dispersion circuit parts 142 can disperse an electro static flowed through the gate line GL so that line disconnection, short-circuit between adjacent lines, or a damage of the TFT can be prevented.

In an embodiment, the first dispersion circuit part 142 is formed at a first end portion of the plurality of gate lines, for example, input part, corresponding to each odd-numbered gate tine GL1, GL3 . . . GL2n-1. The first dispersion line BL1 interconnecting the first dispersion circuit parts 142 is formed in a direction which crosses the plurality of gate lines GL1˜GL2n. When the first dispersion circuit parts 142 are turned on, the odd-numbered gate lines GL1, GL3 . . . GL2n-1 are interconnected so that the electro static can be dispersed.

The second peripheral area PA2 is opposite to the first peripheral area PA1 by interposing the display area therebetween. The second peripheral area PA2 may include a shift register having a plurality of stages, the second gate circuit part 230 to output a gate signal to a second gate lines group of the plurality of gate lines GL1˜GL2n. In an embodiment, the first gate lines group of the plurality of gate lines GL1˜GL2n may include an even-numbered gate lines GL2, GL4 . . . GL2n.

The second peripheral area PA2 may further include second dispersion circuit parts 144, and a second dispersion line BL2 to interconnect the first dispersion circuit parts 144. The second dispersion circuit parts 144 can disperse an etectro static flowed through the gate line GL so that line disconnection short-circuit between adjacent lines, or a damage of the TFT can be prevented.

In an embodiment, the second dispersion circuit part 144 is formed at a second end portion of the plurality of gate lines, for example, input part, corresponding to each even-numbered gate line GL2, GL4 . . . GL2n. The second dispersion line BL2 interconnecting the second dispersion circuit parts 144 is formed in a direction which crosses the plurality of gate lines GL1˜GL2n. When the second dispersion circuit parts 144 are turned on, the even-numbered gate lines GL2, GL4 . . . GL2 are interconnected so that the electro static can be dispersed.

In an embodiment, a first gate lines group and a second gate lines group of the plurality of gate lines GL1˜GL2n can be modified diversely. For example. a first gate lines group of the plurality of gate lines GL1˜GL2n can be a first gate line to a n-th gate line GL1˜GLn, and a second gate lines group of the plurality of gate lines GL1˜GL2n can be a n+1 gate line to a 2n gate tine GL1˜GLn. Moreover, in an embodiment, the first and second dispersion lines BL1 and BL2 are floated, as shown in FIG. 1. Alternatively, the first and second dispersion lines BL1 and BL2 can be grounded. In an embodiment, the first and second dispersion lines BL1 and BL2 can be electrically connected to a common electrode pad (not shown) to connect a common electrode (not shown) that is a second electrode of the liquid crystal capacitor CLC with an external circuit. In an embodiment, the first and second dispersion lines BL1 and BL2 can be electrically grounded to an external ground point through the driving part 210 and the flexible PCB 300.

The driving part 210 having a single chip may be mounted in a third peripheral area PA3. The driving part 210 may include a control part to output various control signals, a first gate control part to output a first gate control signal 210a, a second gate control part to output a second gate control signal 210b, and a data driving part to output a data signal to the plurality of data lines DL1˜DLm.

The fourth peripheral area PA4 is opposite to the third peripheral area PA3 by interposing the display area DA therebetween. The third dispersion line BL3 is formed in the fourth peripheral area PA4 to electrically connect the first dispersion line BL1 formed in the first peripheral area PA1 with the second dispersion line BL2 formed in the second peripheral area PA2.

The countering substrate 120 may include color filter patterns corresponding to each pixel part of the array substrate 110, and a common electrode (not shown) facing the pixel electrode. The common electrode (not shown) acts as a second electrode of the liquid crystal capacitor CLC. Thus, the liquid crystal capacitor CLC is defined by the pixel electrode, the common electrode, and the liquid crystal layer interposed between the pixel electrode and the common electrode. In an embodiment, the color filter patterns may include a red color filter, a green color filter, and/or a blue color filter.

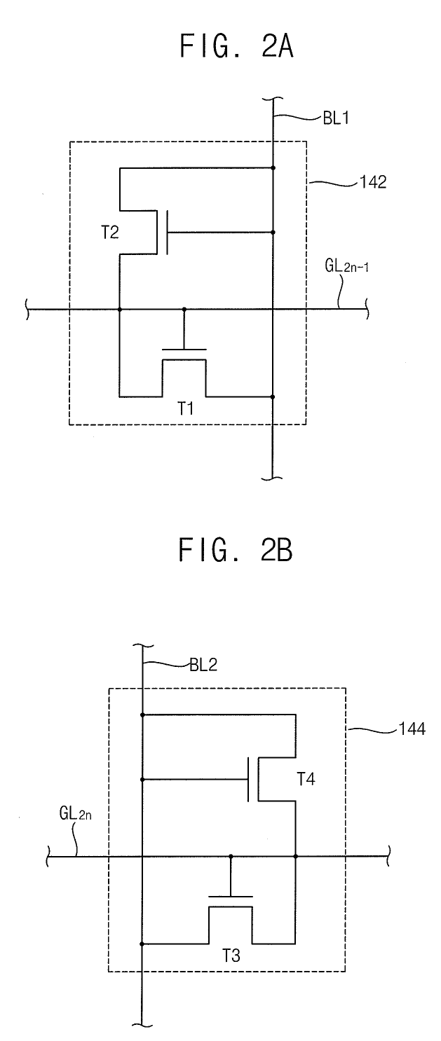

FIG. 2a is an equivalent circuit diagram of a first dispersion circuit part shown in FIG. 1, and FIG. 2b is an equivalent circuit diagram of a second dispersion circuit part shown in FIG. 1.

Referring to FIGS. 1 to 2a, the first dispersion circuit part 142 may include a first transistor T1 and a second transistor T2. A control electrode and a first electrode of the first transistor T1 are electrically connected to an odd-numbered gate line GL2n-1 and a second electrode of the first transistor T1 is connected to the first dispersion line BL1. A control electrode and a first electrode of the second transistor T2 are electrically connected to the first dispersion line BL1, and a second electrode of the transistor T2 is connected to the odd-numbered gate line GL2n-1. In an embodiment, the odd-numbered gate line GL2n-1 can be defined as a first gate lines group.

Referring to FIGS. 1 to 2b, the second dispersion circuit part 144 may include a third transistor T3 and a fourth transistor T4. A control electrode and a first electrode of the third transistor T3 are electrically connected to an even-numbered gate line GL2n, and a second electrode of the third transistor T3 is connected to the second dispersion line BL2. A control electrode and a first electrode of the fourth transistor T4 are electrically connected to the second dispersion line BL2, and a second electrode of the fourth transistor T4 is connected to the even-numbered gate line GL2n. In an embodiment, the even-numbered gate line GL2n can be defined as a second gate lines group.

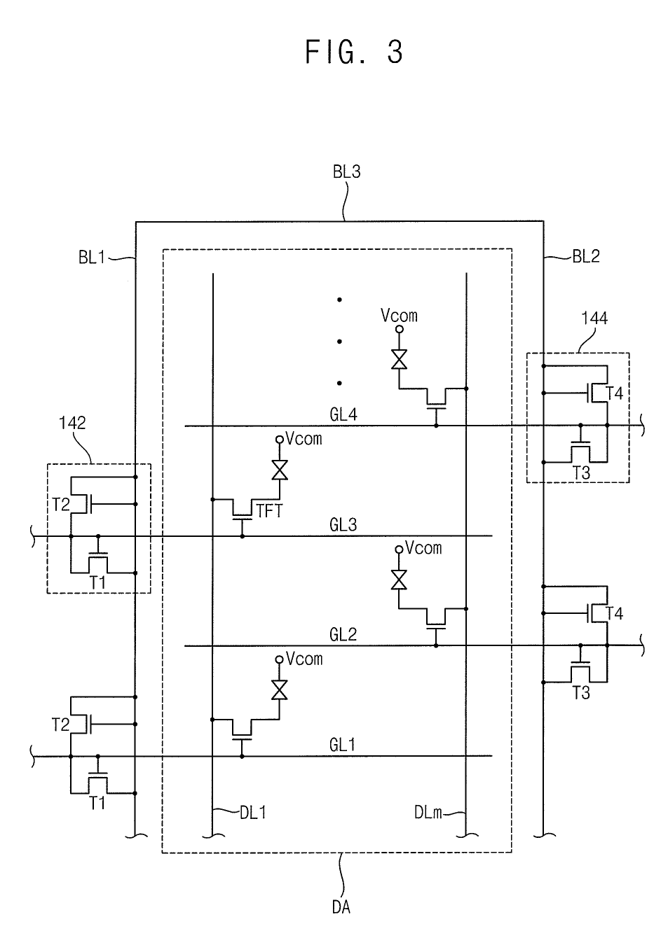

FIG. 3 is an equivalent circuit diagram of a display substrate according to an exemplary embodiment of the present invention. When an electro static is flowed from an exterior to the display panel 100, an operation of the dispersion circuit part and the dispersion line is described.

In an embodiment, when an electro static is flowed to an odd-numbered gate line GL1, the first transistor T1 of the first dispersion circuit part 142 is turned-on by the inflow electro static. The electro static flowed from the odd-numbered gate line GL1 is applied to the first dispersion line BL1 through the first transistor T1.

The second transistor 12 of the first dispersion circuit part 142 is turned-on by the electro static applied to the first dispersion line BL1 through the first transistor T1. Then, the electro static applied to the first dispersion line BL1 is dispersed to the odd-numbered gate lines GL1, GL3 . . . GL2n-1.

Moreover, the electro static of the first dispersion line BL1 is applied to the second dispersion line BL2 through the third dispersion line BL3, and the fourth transistor T4 of the second dispersion circuit part 144 is turned-on by the electro static applied to the second dispersion line BL2. Thus, electro static applied to the second dispersion line BL2 is dispersed to the even-numbered gate lines GL2, GL4 . . . GL2n.

The electro static flowed to the odd-numbered gate line GL1 turns on the first transistor T1, and the electro static is applied to the first to third dispersion line BL1, BL2, BL3. The electro static flowed to the first to third dispersion line BL1, BL2, BL3 turns on the second and fourth transistors T2, T4. Thus, the inflow electro static can be dispersed to the remaining gate lines GL2˜GL2n.

Alternatively, the electro static flowed to the even-numbered gate line GL2 turns on the first transistor T3, and the electro static is applied to the first to third dispersion line BL1, BL2, BL3. The electro static flowed to the first to third dispersion line BL1, BL2, BL3 turns on the second and fourth transistors T2, T4. Thus, the inflow electro static can be dispersed to the remaining gate lines.

According to an exemplary embodiment of the present invention, the electro static flowed to the gate line can be dispersed to the plurality of gate lines GL1˜GL2n through the first and second dispersion circuit parts 142, 144 and the first to third dispersion lines BL1, BL2, BL3 so that damages caused by the electro static can be reduced. Moreover, at least one of the first dispersion line BL1 and the second dispersion line BL2 is grounded so that damages caused by the electro static can be reduced.

The first dispersion circuit part 142 and the second dispersion circuit part 144 include a transistor. In an embodiment, the first dispersion circuit part 142 and the second dispersion circuit part 144 may include an element having one directional current flow. For example the first dispersion circuit part 142 and the second dispersion circuit part 144 may include a plurality of diodes.

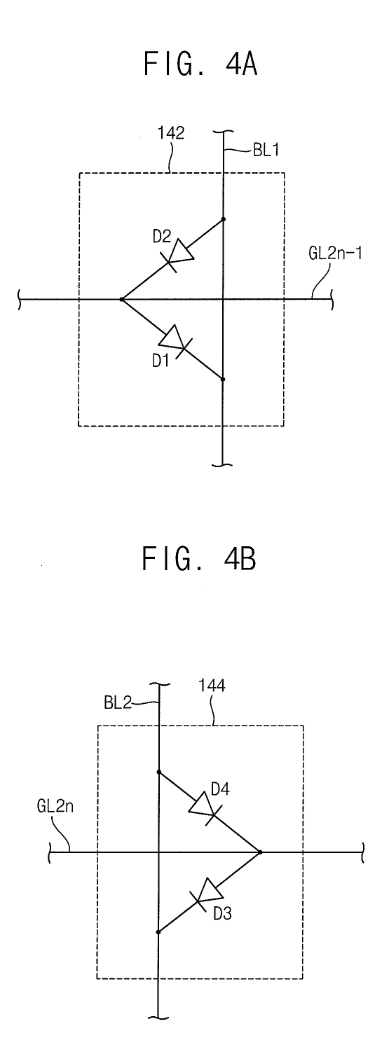

FIG. 4a is an equivalent circuit diagram of a first dispersion circuit part shown in FIG. 1 according to an exemplary embodiment of the present invention, and FIG. 4b is an equivalent circuit diagram of a second dispersion circuit part shown in FIG. 1 according to an exemplary embodiment of the present invention.

Referring to FIGS. 1 to 4a, a first dispersion circuit part 142 may include a first diode D1 and a second diode D2. An anode of the first diode D1 is connected to an odd-numbered gate line GL2n-1, a cathode of the first diode D1 is connected to a first dispersion line BL1. An anode of the second diode D2 is connected to the first dispersion line BL1, and a cathode of the second diode D2 is connected to the odd-numbered gate line GL2n-1.

Referring to FIGS. 1 to 4b, a second dispersion circuit part 144 may include a third diode D3 and a fourth diode D4. An anode of the third diode D3 is connected to an even-numbered gate line GL2n, and a cathode of the third diode D3 is connected to a second dispersion line BL2. An anode of the fourth diode D4 is connected to the second dispersion line BL2, a cathode of the fourth diode D4 is connected to the even-numbered gate line GL2n. The first to fourth diodes D1, D2, D3, D4 having one directional current flow may act as the first to fourth transistors T1, T2, T3, T4.

According to exemplary embodiments of the present invention, the electro static flowed to the gate line can be dispersed to the plurality of gate lines GL1˜GL2n through the first and second dispersion circuit parts and the first to third dispersion lines so that damages caused by the electro static can be reduced. Moreover, the dispersion line is grounded so that damages caused by the electro static can be reduced.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A display substrate comprising:
a base substrate having a display area displaying an image and a peripheral area surrounding the display area, the base substrate including a plurality of gate lines comprising a first gate line group and a second gate line group;
a first dispersion circuit part formed at a first end portion of the first gate line group;
a second dispersion circuit part formed at a second end portion of the second gate line group;
a first dispersion line electrically connected to the first gate line group through the first dispersion circuit part;
a second dispersion line electrically connected to the second gate line group through the second dispersion circuit part; and
a third dispersion line connecting the first dispersion line with the second dispersion line.

2. The display substrate of claim 1, wherein the peripheral area includes a first peripheral area disposed at a first end portion of the plurality of gate lines and a second peripheral area disposed at a second end portion of the plurality of gate lines.

3. The display substrate of claim 2, wherein the first dispersion circuit part and the first dispersion line are formed in the first peripheral area, and the second dispersion circuit part and the second dispersion lines are formed in the second peripheral area.

4. The display substrate of claim 2, wherein the first dispersion circuit part comprises:
a first transistor including a control electrode, a first electrode connected to the first gate line group, and a second electrode connected to the first dispersion line; and
a second transistor including a control electrode, a first electrode connected to the first dispersion line, and a second electrode connected to the first gate line group.

5. The display substrate of claim 4, wherein the second dispersion circuit part comprises:
a third transistor including a control electrode, a first electrode connected to the second gate line group, and a second electrode connected to the second dispersion line; and
a fourth transistor including a control electrode, a first electrode connected to the second dispersion line, and a second electrode connected to the second gate line group

6. The display substrate of claim 2, wherein the first dispersion circuit part comprises:
a first diode including an anode connected to the first gate line group and a cathode connected to the first dispersion line; and
a second diode including an anode connected to the first dispersion line and a cathode connected to the first gate line group.

7. The display substrate of claim 6, wherein the second dispersion circuit part comprises:
a third diode including an anode connected to the second gate line group and a cathode connected to the second dispersion line; and
a fourth diode including an anode connected to the second dispersion line and a cathode connected to the second gate line group.

8. The display substrate of claim 2, wherein the first gate line group includes odd-numbered gate lines and the second gate line group includes even-numbered gate lines.

9. The display substrate of claim 2, wherein the third dispersion line is formed in the peripheral area.

10. A display device comprising:
an array substrate having a display area displaying an image and a peripheral area surrounding the display area, the array substrate including a plurality of gate lines comprising a first gate line group and a second gate line group;
a first dispersion circuit part formed at a first end portion of the first gate line group;
a second dispersion circuit part formed at a second end portion of the second gate line group;
a first dispersion line electrically connected to the first gate line group through the first dispersion circuit part;
a second dispersion line electrically connected to the second gate line group through the second dispersion circuit part;
a third dispersion line connecting the first dispersion line with the second dispersion line;
a countering substrate facing the array substrate;
a first gate circuit part to drive the first gate line group; and
a second gate circuit part to drive the second gate line group.

11. The display device of claim 10, wherein the first dispersion circuit part, the second dispersion circuit part, the first dispersion line, the second dispersion line and the third dispersion line are formed in the peripheral area.
